(19) United States
(12) Patent Application Publication
(10) Pub. No.: US 2013/0187627 A1
(43) Pub. Date: Jul. 25, 2013

(54) SEMICONDUCTOR DEVICE AND POWER SUPPLY DEVICE

(71) Applicant: FUJITSU LIMITED, Kawasaki-shi (JP)

(72) Inventors: Tadahiro IMADA, Kawasaki (JP); Tatsuya HIROSE, Yokohama (JP)

(73) Assignee: FUJITSU LIMITED, Kawasaki-shi (JP)

(21) Appl. No.: 13/731,342

(22) Filed: Dec. 31, 2012

(30) Foreign Application Priority Data
Jan. 24, 2012 (JP) 2012-012507

(51) Int. Cl. H01L 27/088; G05F 3/08

(52) U.S. Cl. CPC H01L 27/088; G05F 3/08
USPC 323/311; 257/76

(57) ABSTRACT

A semiconductor device includes: a lead frame that is composed of a lead and a die stage; a GaN-HEMT that is disposed on the die stage and has a source electrode on a rear surface of the GaN-HEMT, the source electrode being connected to the die stage; and a MOS-FET that is disposed on the die stage and has a drain electrode on a rear surface of the MOS-FET, the drain electrode being connected to the die stage; wherein the source electrode of the GaN-HEMT and the drain electrode of the MOS-FET are cascode-connected with each other via the die stage.

### CROSS-REFERENCE TO RELATED APPLICATION

This application is based upon and claims the benefit of priority of the prior Japanese Patent Application No. 2012-12507, filed on Jan. 24, 2012, the entire contents of which are incorporated herein by reference.

### FIELD

The embodiments discussed herein are related to a semiconductor device including a compound semiconductor device, and a power supply device.

### BACKGROUND

In recent years, an electronic device (compound semiconductor device) that is obtained by sequentially forming a GaN layer and an AlGaN layer on a substrate which is made of sapphire, SiC, gallium nitride (GaN), Si, or the like and of which the GaN layer is used as an electron transit layer has been actively developed.

A bandgap of GaN is 3.4 eV which is larger than 1.1 eV which is a bandgap of Si and 1.4 eV which is a bandgap of GaAs. Therefore, this compound semiconductor device is expected to operate under high withstand voltage.

As an example of such compound semiconductor device, a GaN based high electron mobility transistor (HEMT) is sited. Hereinafter, this GaN based high electron mobility transistor is referred to as a GaN-HEMT.

In a case where a GaN-HEMT is used as a switch of an inverter for power source, reduction of on-resistance and improvement of withstand voltage are compatible. Further, standby power consumption may be reduced and an operation frequency may be improved compared to a Si based transistor.

Therefore, switching loss may be reduced and power consumption of an inverter may be lowered. Further, in a case of a transistor exhibiting an equivalent performance, a GaN-HEMT may be reduced in size compared to a Si based transistor.

The following is reference document:

### [Document 1] Japanese Laid-open Patent Publication No. 2006-223016

### [Document 2] Japanese Laid-open Patent Publication No. 2008-311653

### [Document 3] Japanese National Publication of International Patent Application No. 2008-522436

### SUMMARY

According to an aspect of the invention, a semiconductor device includes: a lead frame that is composed of a lead and a die stage; a GaN-HEMT that is disposed on the die stage and has a source electrode on a rear surface of the GaN-HEMT, the source electrode being connected to the die stage; and a MOS-FET that is disposed on the die stage and has a drain electrode on a rear surface of the MOS-FET, the drain electrode being connected to the die stage; wherein the source electrode of the GaN-HEMT and the drain electrode of the MOS-FET are cascode-connected with each other via the die stage.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF DRAWINGS

FIG. 1 is a configuration diagram of a GaN-HEMT;

FIG. 2 is a circuit diagram of a cascade connection circuit;

FIGS. 3A and 3B illustrate the configuration of a semiconductor device in which a GaN-HEMT and a MOS-FET are integrated;

FIGS. 4A and 4B illustrate a waveform of source voltage of the GaN-HEMT;

FIGS. 5A and 5B illustrate the configuration of a semiconductor device according to a first embodiment;

FIG. 6 is a sectional view of a GaN-HEMT according to the first embodiment;

FIG. 7 is a sectional view of a MOS-FET according to the first embodiment;

FIG. 8 is a circuit diagram of a semiconductor device according to a second embodiment;

FIGS. 9A and 9B illustrate the configuration of the semiconductor device according to the second embodiment; and

FIG. 10 illustrates the configuration of a power supply device to which the semiconductor device of the first embodiment is applied.

### DESCRIPTION OF EMBODIMENTS

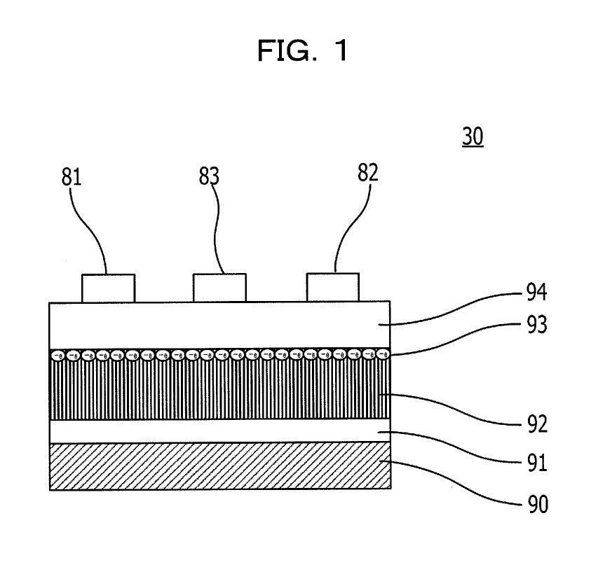

A common GaN-HEMT is first described. FIG. 1 is a sectional view illustrating the configuration of a common GaN-HEMT 30. An AlN layer 91, a non-doped i-GaN layer 92, and an n-type n-AlGaN layer 94 are sequentially formed on a SiC substrate 90.

Further, a source electrode 81, a drain electrode 82, and a gate electrode 83 are formed on the n-AlGaN layer 94. In the GaN-HEMT 30, a two-dimensional electron gas 93 which is formed on an interface of the n-AlGaN layer 94 with respect to the i-GaN layer 92 is used as a carrier. Here, the AlN layer 91 serves as a buffer layer.

However, a MOS-FET of related art which is made of silicon is turned off in a state that no voltage is applied to a gate, that is, the MOS-FET of related art is of normally-off type (enhancement type) MOS-FET, while a GaN-HEMT is commonly turned on in a state that no voltage is applied to a gate, that is, the GaN-HEMT is of normally-on type (depression type) GaN-HEMT.

Therefore, negative power has to be used for switching a GaN-HEMT of the depression type, but a negative power generation circuit is large in circuit size and the cost is increased, being unfavorable.

Alternatively, there is a method which is cascode connection in which such depression type GaN-HEMT is combined with a depression type FET so as to work as an enhancement type GaN-HEMT.

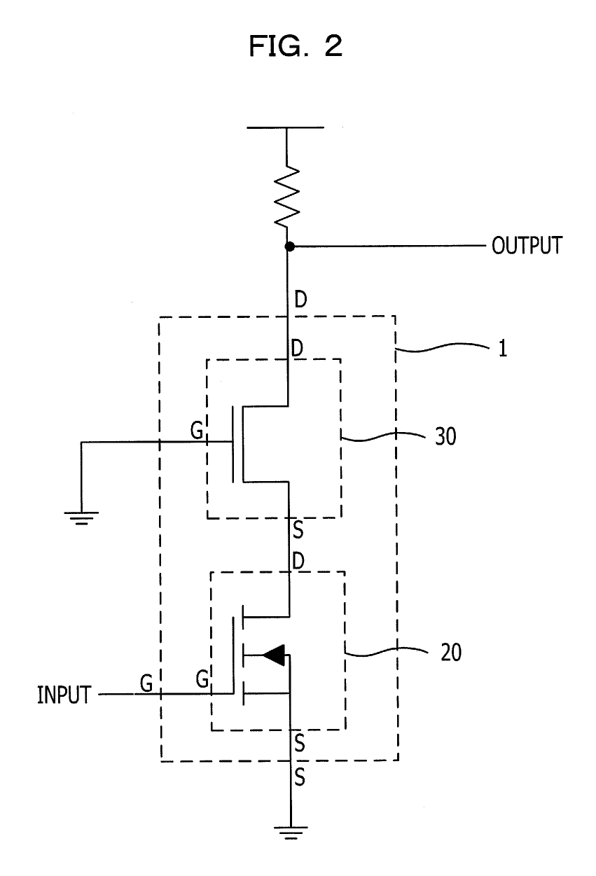

FIG. 2 illustrates an example of a cascode connection circuit. A cascode connection circuit 1 includes the depression type GaN-HEMT 30 and an enhancement type MOS-FET 20 that are connected in series. A source of the depression type GaN-HEMT 30 is connected to a drain of the enhancement type MOS-FET 20. The enhancement type MOS-FET 20 is a silicon-based n-type MOS-FET which is commonly available, for example.

A gate of the GaN-HEMT 30 and a source of the MOS-FET 20 are grounded. A drain of the GaN-HEMT 30 functions as a drain of the cascode connection circuit 1 and the source of the MOS-FET 20 functions as a source of the cascode connection circuit 1. In a similar manner, a gate of the MOS-FET 20 functions as a gate of the cascode connection circuit 1.

In a case of the cascode connection circuit 1, the enhancement type MOS-FET 20 is newly added, so that a mounting space for the enhancement type MOS-FET 20 has to be secured on a circuit substrate. Therefore, there is such method that the cascode connection circuit 1 is incorporated in a single semiconductor device so as to mount the semiconductor device in the mounting space for the GaN-HEMT 30.

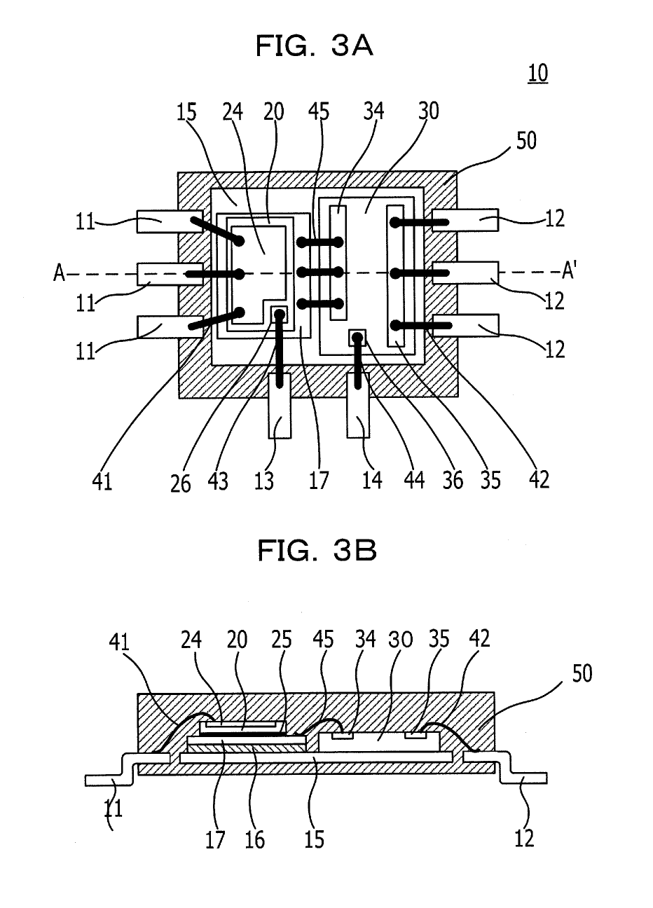

FIGS. 3A and 3B illustrate an example of a semiconductor device in which the depression type GaN-HEMT 30 and the enhancement type MOS-FET 20 are incorporated in a single package. FIG. 3A is a plan perspective view and FIG. 3B is a sectional view of a A-A′ plane of FIG. 3A.

In a semiconductor device 10 which is an example, the depression type GaN-HEMT 30 and the enhancement type MOS-FET 20 are mounted on a die stage 15 which is made of metal such as copper and has a plate-like shape.

A source electrode pad 24 provided on a surface of the enhancement type MOS-FET 20 and a source lead terminal 11 which is an external terminal of the semiconductor device 10 are connected with each other by a bonding wire 41. A gate electrode pad 26 provided on the surface of the enhancement type MOS-FET 20 and a gate lead terminal 13 which is an external terminal of the semiconductor device 10 are connected with each other by a bonding wire 43.

Referring to FIG. 3B, the enhancement type MOS-FET 20 is disposed on the die stage 15 with an insulation plate 16 and a metal plate 17 interposed therebetween. On a rear surface of the enhancement type MOS-FET 20, a drain electrode pad 25 is formed and fixed on the metal plate 17 by a conducting material such as a soldering paste (not depicted).

A drain electrode pad 35 provided on a surface of the depression type GaN-HEMT 30 and a drain lead terminal 12 which is an external terminal of the semiconductor device 10 are connected with each other by a bonding wire 42. A gate electrode pad 36 provided on the surface of the depression type GaN-HEMT 30 and a gate lead terminal 14 which is an external terminal of the semiconductor device 10 are connected with each other by a bonding wire 44.

A source electrode pad 34 provided on the surface of the depression type GaN-HEMT 30 and the metal plate 17 which is provided below the enhancement type MOS-FET 20 are connected with each other by a bonding wire 45. Therefore, the drain electrode pad 25 of the enhancement type MOS-FET 20 and the source electrode pad 34 of the depression type GaN-HEMT 30 are electrically connected with each other via the metal plate 17 and the bonding wire 45. Thus, the enhancement type MOS-FET 20 and the depression type GaN-HEMT 30 are cascode-connected.

The die stage 15, the source lead terminal 11, the drain lead terminal 12, the gate lead terminal 13, and the gate lead terminal 14 are commonly parts of a lead frame which are formed by etching or punching a single sheet of metal plate made of copper or the like.

The depression type GaN-HEMT 30, the enhancement type MOS-FET 20, and the bonding wires 41, 42, 43, 44, and 45 are sealed by resin 50 and parts of the source lead terminal 11, the drain lead terminal 12, the gate lead terminal 13, and the gate lead terminal 14 are derived from the resin 50 so as to become external terminals of the semiconductor device 10.

In case of using a depression type GaN-HEMT, the depression type GaN-HEMT may be used as a GaN-HEMT of a normally-off type by replacing with the semiconductor device 10 and further, a mounting space for one GaN-HEMT is sufficient.

However, problems such as breakdown of the depression type GaN-HEMT 30 and a state that the depression type GaN-HEMT 30 is not turned on or off have been generated.

The inventor investigated the problems, which arose in the semiconductor device described as an example, such as the breakdown of the depression type GaN-HEMT 30 and the state that the depression type GaN-HEMT 30 was not turned on or off.

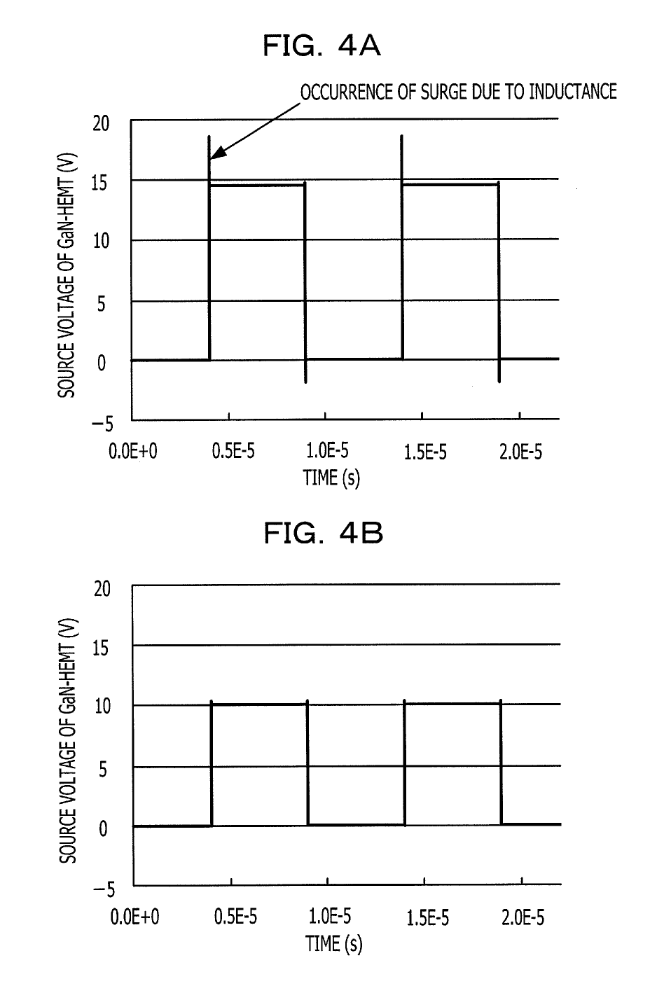

FIG. 4A illustrates a source voltage of the depression type GaN-HEMT 30 in the semiconductor device 10. As depicted in FIG. 4A, it was observed that serge voltage was generated at rise of source voltage of the depression type GaN-HEMT 30. It has been understood that when voltage larger than the rating is applied between a source and a gate in the MOS-FET and in the GaN-HEMT, breakdown or malfunction occurs.

Further, distortion of a rising waveform and a falling waveform of source voltage of the depression type GaN-HEMT 30 was also observed.

In the semiconductor device 10 which is an example, the drain electrode pad 35 provided on the surface of the depression type GaN-HEMT 30 and the drain lead terminals 12 which are the external terminals of the semiconductor device 10 are connected by three bonding wires 42 respectively. Further, the source electrode pad 24 provided on the surface of the enhancement type MOS-FET 20 and the source lead terminals 11 which are the external terminals of the semiconductor device 10 are connected by three bonding wires 41 respectively. On the other hand, the source electrode pad 34 on the depression type GaN-HEMT 30 and the drain electrode pad 25 on the enhancement type MOS-FET 20 are connected with each other by the bonding wire 45 via the metal plate 17. Therefore, wiring length is longer than other bonding wires, so that parasitic inductance easily occurs.

The inventor considered that the above-mentioned surge and waveform distortion were caused by the parasitic inductance occurring in connection between the source of the depression type GaN-HEMT 30 and the drain of the enhancement type MOS-FET 20, and invented the following embodiments.

Preferred embodiments according to the present disclosure are now described in detail below in reference to the accompanying drawings.

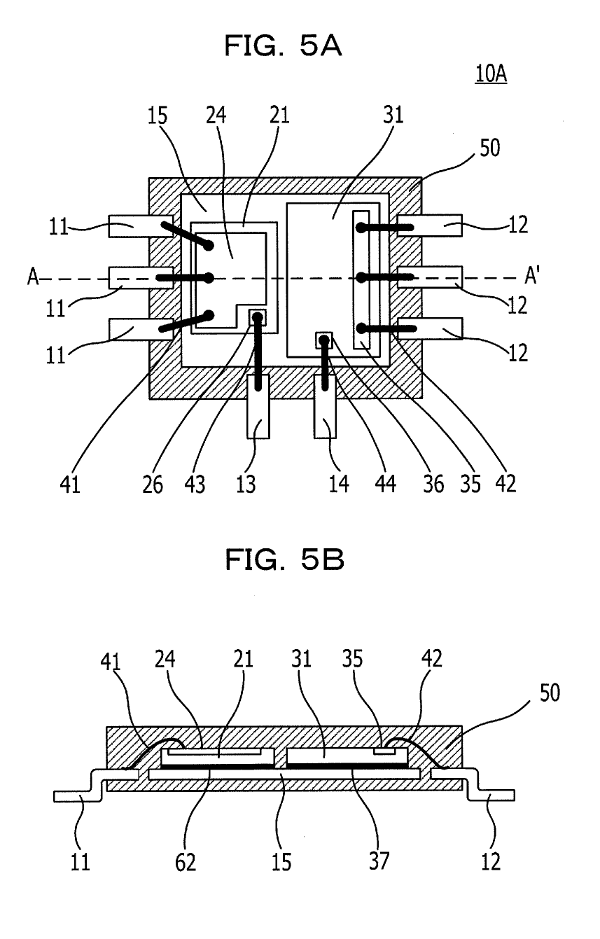

FIGS. 5A and 5B illustrate the configuration of a semiconductor device according to a first embodiment of the present disclosure. In FIGS. 5A and 5B, constituting elements which are same as or equivalent to those of the semiconductor device 10 depicted in FIGS. 3A and 3B are given the same reference numerals and the description thereof is omitted.

FIG. 5A is a plan perspective view of a semiconductor device 10A of the first embodiment and FIG. 5B is a sectional view of a A-A′ plane of FIG. 5A.

In the semiconductor device 10A, a depression type GaN-HEMT 31 and an enhancement type MOS-FET 21 are mounted on a die stage 15 which is made of metal such as copper and has a plate-like shape.

A source electrode pad 24 provided on a surface of the enhancement type MOS-FET 21 and a source lead terminal 11 which is an external terminal of the semiconductor device 10A are connected with each other by a bonding wire 41. A gate electrode pad 26 provided on the surface of the enhancement type MOS-FET 21 and a gate lead terminal 13 which is an external terminal of the semiconductor device 10A are connected with each other by a bonding wire 43. The source electrode pad 24 of the enhancement type MOS-FET 21 of the first embodiment is provided in a region, on the surface of the enhancement type MOS-FET 21, except for the gate electrode pad 26. Here, on the surface of the enhancement type MOS-FET 21 of the first embodiment, a drain electrode pad is not provided.

A drain electrode pad 35 provided on a surface of the depression type GaN-HEMT 31 and a drain lead terminal 12 which is an external terminal of the semiconductor device 10A are connected with each other by a bonding wire 42. A gate electrode pad 36 provided on the surface of the depression type GaN-HEMT 30 and a gate lead terminal 14 which is an external terminal of the semiconductor device 10A are connected with each other by a bonding wire 44. Here, on the surface of the depression type GaN-HEMT 31 of the first embodiment, a source electrode pad is not provided.

The depression type GaN-HEMT 31, the enhancement type MOS-FET 21, and the bonding wires 41, 42, 43, and 44 are sealed by resin 50, and parts of the source lead terminal 11, the drain lead terminal 12, the gate lead terminal 13, and the gate lead terminal 14 are derived from the resin 50 so as to become external terminals of the semiconductor device 10A.

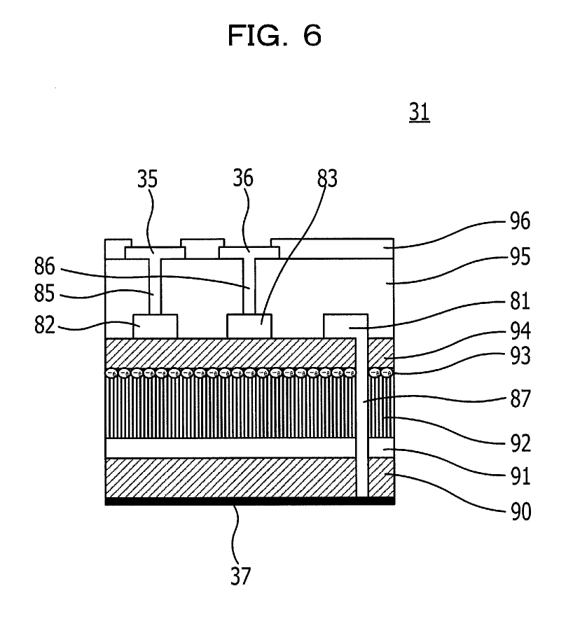

Subsequently, the configuration of the depression type GaN-HEMT 31 which is used in the semiconductor device 10A according to the first embodiment is described with reference to FIG. 6. FIG. 6 is a schematic sectional view of the depression type GaN-HEMT 31.

An AlN layer 91, a non-doped i-GaN layer 92, and an n-type n-AlGaN layer 94 are sequentially formed on a SiC substrate 90. Further, a drain electrode 82, a gate electrode 83, and a source electrode 81 are formed on the n-AlGaN layer 94. In the GaN-HEMT 31, a two-dimensional electron gas 93 which is formed on an interface of the n-AlGaN layer 94 with respect to the i-GaN layer 92 is used as a carrier. Here, the AlN layer 91 serves as a buffer layer.

Further, an inter-layer insulating film 95 which is made of an insulating material such as polyimide is formed on the n-type n-AlGaN layer 94, the source electrode 81, the drain electrode 82, and the gate electrode 83.

On this inter-layer insulating film 95, a drain electrode pad 35 and a gate electrode pad 36 are formed. The drain electrode 82 and the drain electrode pad 35 are electrically connected with each other by a contact plug 85 which is formed in the inter-layer insulating film 95, and the gate electrode 83 and the gate electrode pad 36 are electrically connected with each other by a contact plug 86 which is formed in the inter-layer insulating film 95. A surrounding area of the drain electrode pad 35 and the gate electrode pad 36 is covered by a cover film 96.

On a rear surface of the depression type GaN-HEMT 31, that is, on a bottom surface of the SiC substrate 90, a conducting film is formed so as to be a source electrode terminal 37 of the GaN-HEMT 31. The source electrode terminal 37 and the source electrode 81 are electrically connected with each other by a contact plug 87 which penetrates through the SiC substrate 90, the AlN layer 91, the non-doped i-GaN layer 92, and the n-type n-AlGaN layer 94.

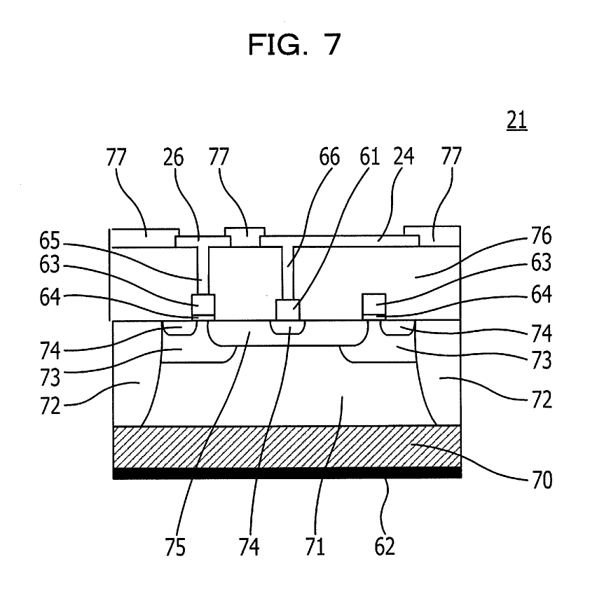

Subsequently, the configuration of the enhancement type MOS-FET 21 which is used in the semiconductor device 10A according to the first embodiment is described with reference to FIG. 7. FIG. 7 is a schematic sectional view of the enhancement type MOS-FET 21.

In the enhancement type MOS-FET 21, a p− epi layer 71, a channel layer 73, an n− drift layer 75, and an n+ layer 74 are formed on a p-type substrate 70. On the channel layer 73 formed between the n− drift layer 75 and the n+ layer 74, a gate electrode 63 is formed with a gate oxide film 64 interposed therebetween. Further, on the n+ layer 74 formed in the n− drift layer 75, a source electrode 61 is formed. On a circumference of the p− epi layer 71 formed on the p-type substrate 70, a p+ punching layer 72 is provided. On the rear surface of the enhancement type MOS-FET 21, that is, on the bottom surface of the p-type substrate 70, a conducting film which is a drain electrode 62 is formed.

Further, on the p+ punching layer 72, the n+ layer 74, the n− drift layer 75, the gate electrode 63, and the source electrode 61, an inter-layer insulating film 76 which is made of an insulating material such as polyimide is formed.

On this inter-layer insulating film 76, a source electrode pad 24 and a gate electrode pad 26 are formed. The source electrode 61 and the source electrode pad 24 are electrically connected with each other by a contact plug 66 which is formed in the inter-layer insulating film 76, and the gate electrode 63 and the gate electrode pad 26 are electrically connected with each other by a contact plug 65 which is formed in the inter-layer insulating film 76. A surrounding area of the source electrode pad 24 and the gate electrode pad 26 is covered by a cover film 77.

Referring to FIG. 5B, the enhancement type MOS-FET 21 and the depression type GaN-HEMT 31 that are used in the semiconductor device 10A according to the first embodiment are fixed on the die stage 15 by a conducting material such as a soldering paste (not depicted).

The enhancement type MOS-FET 21 is mounted so that the drain electrode 62 provided on the bottom surface of the enhancement type MOS-FET 21 faces the die stage 15. Though a conducting material such as a soldering paste is interposed, the drain electrode 62 of the enhancement type MOS-FET 21 and the die stage 15 are brought into surface contact with each other.

The depression type GaN-HEMT 31 is mounted so that the source electrode terminal 37 provided on the bottom surface of the depression type GaN-HEMT 31 faces the die stage 15. Though the conducting material such as a soldering paste is interposed, the source electrode terminal 37 of the depression type GaN-HEMT 31 and the die stage 15 are brought into surface contact with each other.

Since the die stage is a conductor made of metal such as copper, the drain electrode 62 of the enhancement type MOS-FET 21 and the source electrode terminal 37 of the depression type GaN-HEMT 31 are electrically connected with each other via the die stage 15.

FIG. 4B illustrates source voltage of the depression type GaN-HEMT 31 provided in the semiconductor device 10A according to the first embodiment. As depicted in FIG. 4B, it was confirmed that surge voltage was not generated at rise of source voltage of the depression type GaN-HEMT 31. Further, it was also confirmed that distortion of a rising waveform and a falling waveform of source voltage of the depression type GaN-HEMT 31 did not occur and a clear ON/OFF waveform was obtained.

According to the semiconductor device 10A of the first embodiment, surge of source voltage and waveform distortion of the depression type GaN-HEMT of the semiconductor device 10 which is an example do not occur so that malfunction, breakdown, and the like of the GaN-HEMT hardly occur. Thus, a highly-efficient and highly-reliable semiconductor device may be provided.

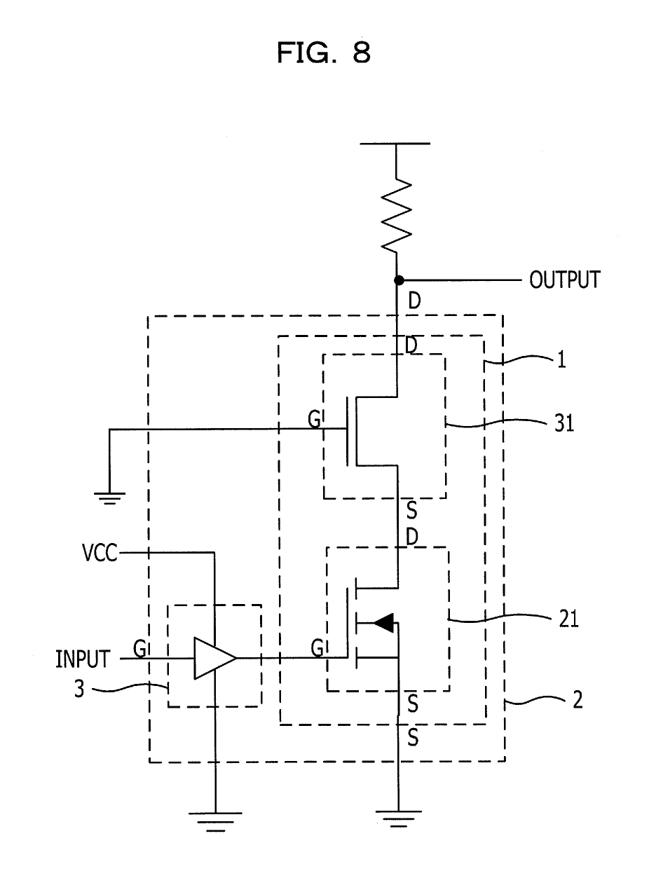

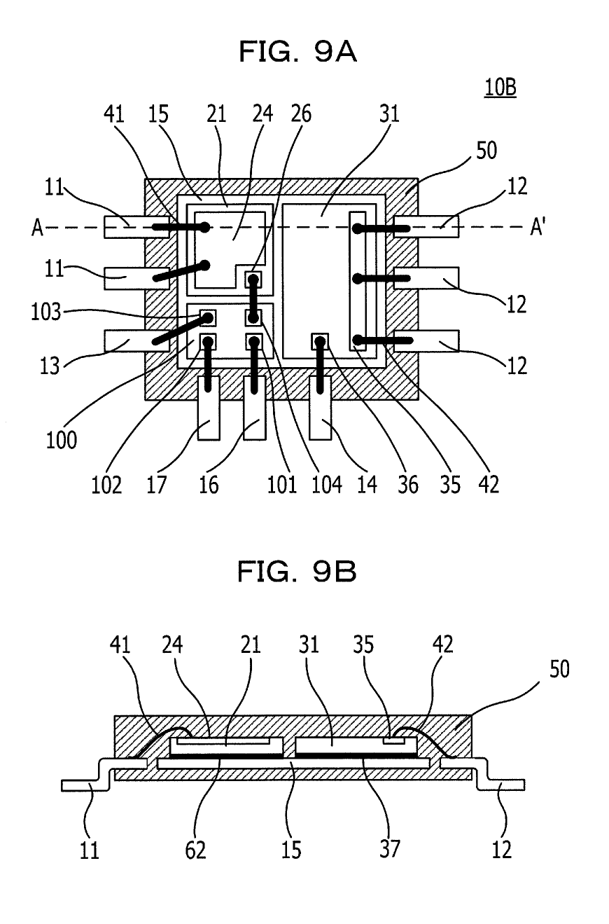

A semiconductor device according to a second embodiment of the present disclosure is now described with reference to FIGS. 8 to 9B. FIG. 8 illustrates the circuit configuration of the semiconductor device according to the second embodiment. A circuit 2 of the semiconductor device according to the second embodiment includes a driver circuit 3 for a signal for controlling ON/OFF of the cascode connection circuit 1, in addition to the cascode connection circuit 1 which is described with reference to FIG. 2. The driver circuit 3 converts a voltage level of a signal which is inputted into a gate of an enhancement type MOS-FET, in synchronization with a threshold value of the enhancement type MOS-FET provided in the cascode connection circuit 1. The semiconductor device may further include a pulse width modulation (PWM) signal generation circuit for turning ON/OFF the gate.

FIGS. 9A and 9B illustrate the configuration of the semiconductor device according to the second embodiment. FIG. 9A is a plan perspective view of a semiconductor device 10B of the second embodiment and FIG. 9B is a sectional view of a A-A′ plane of FIG. 9A. Constituting elements which are same as or equivalent to those of the semiconductor device 10A of the first embodiment depicted in FIGS. 5A and 5B are given the same reference numerals and the description thereof is omitted.

A depression type GaN-HEMT 31, an enhancement type MOS-FET 21, and a control chip 100 including the driver circuit 3 are mounted on a die stage 15 which is made of metal such as copper and has a plate-like shape.

On a surface of the control chip 100, four electrode pads which are a power source pad 101, a grounding pad 102, an input signal pad 103, and an output signal pad 104 are formed.

The power source pad 101 and a power source lead terminal 16 which is an external terminal of the semiconductor device 10B are connected with each other by a bonding wire. The grounding pad 102 and a ground lead terminal 17 which is an external terminal of the semiconductor device 10B are connected with each other by a bonding wire. The input signal pad 103 and a gate lead terminal 13 which is an external terminal of the semiconductor device 10B are connected with each other by a bonding wire. The output signal pad 104 and a gate electrode pad 26 provided on the enhancement type MOS-FET 21 are connected with each other by a bonding wire. Other connections are same as those of the semiconductor device 10A of the first embodiment.

The depression type GaN-HEMT 31, the enhancement type MOS-FET 21, the control chip 100, and the bonding wires 41, 42, 43, and 44 are sealed by resin 50 and parts of the source lead terminal 11, the drain lead terminal 12, the gate lead terminal 13, the gate lead terminal 14, the power source lead terminal 16, and the ground lead terminal 17 are derived from the resin 50 so as to become external terminals of the semiconductor device 10B.

Referring to FIG. 9B, the enhancement type MOS-FET 21 and the depression type GaN-HEMT 31 are fixed on the die stage 15 by a conducting material such as a soldering paste (not depicted) in the semiconductor device 10B according to the second embodiment as well. The enhancement type MOS-FET 21 is mounted so that the drain electrode 62 provided on the bottom surface of the enhancement type MOS-FET 21 faces the die stage 15, while the depression type GaN-HEMT 31 is mounted so that the source electrode terminal 37 provided on the bottom surface of the depression type GaN-HEMT 31 faces the die stage 15. Accordingly, the drain electrode 62 of the enhancement type MOS-FET 21 and the source electrode terminal 37 of the depression type GaN-HEMT 31 are electrically connected with each other via the die stage 15. The connection between the drain electrode 62 of the enhancement type MOS-FET 21 and the die stage 15 and the connection between the source electrode terminal 37 of the depression type GaN-HEMT 31 and the die stage 15 are surface connection, so that impedance between the drain electrode 62 and the die stage 15 and between the source electrode terminal 37 and the die stage 15 is significantly small and parasitic inductance is significantly low.

According to the semiconductor device 10B of the second embodiment, an effect of parasitic inductance, which has been generated in the semiconductor device 10 which is an example, between a source electrode of the depression type GaN-HEMT and a drain electrode of the enhancement type MOS-FET is not exhibited, so that problems which are malfunction, breakdown, and the like of the GaN-HEMT hardly occur, being able to provide a highly-reliable semiconductor device.

Finally, a case where the semiconductor device 10A of the first embodiment is used as a switching element of a switching power supply (power supply device) such as a server or the like which steps down relatively-high voltage and supplies power to the inside of the device is described. In a common switching power supply, a high withstand voltage MOS-FET is used as a switching element.

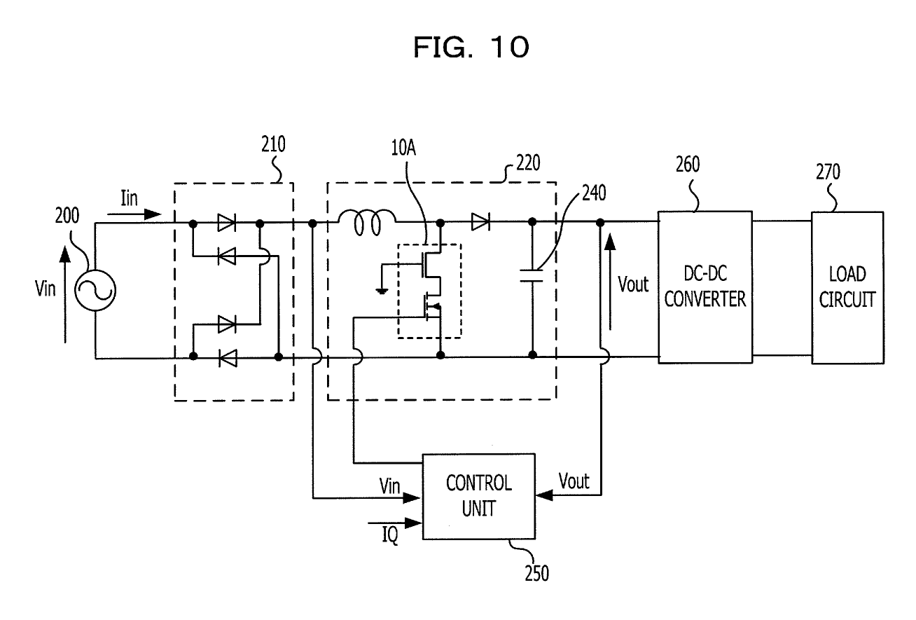

FIG. 10 is a circuit diagram of a power supply device in which a power factor correction (PFC) circuit for improving a power factor of a power source is provided. The power supply device depicted in FIG. 10 includes a rectification circuit 210, a PFC circuit 220, a control unit 250, and a DC (direct current)-DC converter 260.

The rectification circuit 210 is connected with an AC source 200 and full-wave rectifies AC power so as to output the rectified AC power. Here, output voltage of the AC source 200 is Vin, so that input voltage of the rectification circuit 210 is Vin. The rectification circuit 210 outputs power obtained by full-wave rectifying AC power which is received from the AC source 200. AC power of which voltage is 80 (V) to 265 (V), for example, is inputted into the rectification circuit 210, so that output voltage of the rectification circuit 210 is also Vin.

The PFC circuit 220 includes an inductor, a switching element (the semiconductor device 10A of the first embodiment), and a diode that are connected in a T-shaped fashion, and a smoothing capacitor 240. The PFC circuit 220 is an active filter circuit which reduces distortion of harmonic or the like contained in current, which is rectified by the rectification circuit 210, so as to improve a power factor of power.

The control unit 250 outputs pulsed gate voltage which is applied to a gate of the switching element 10A. The control unit 250 determines a duty ratio of gate voltage on the basis of a voltage value Vin of full-wave rectified power which is outputted from the rectification circuit 210, a current value of current flowing in the switching element 10A, and a voltage value Vout on an output side of the smoothing capacitor 240 and applies the gate voltage to the gate of the switching element 10A. As the control unit 250, a multiplier circuit which may calculate a duty ratio on the basis of a current value of current flowing in the switching element 10A, a voltage value Vout, and a voltage value Vin may be used, for example.

The smoothing capacitor 240 smoothes voltage, which is outputted from the PFC circuit 220, so as to input the smoothed voltage into the DC-DC converter 260. As the DC-DC converter 260, a forward type or full-bridge type DC-DC converter may be used, for example. Into the DC-DC converter 260, DC power of which voltage is 385 (V), for example, is inputted.

The DC-DC converter 260 is a converting circuit which converts a voltage value of DC power so as to output the DC power. To the output side of the DC-DC-converter 260, a load circuit 270 is connected.

Here, the DC-DC converter 260 converts DC power having voltage of 385 (V) into DC power having voltage of 12 (V), for example, so as to output the DC power to the load circuit 270.

According to the embodiments, a switching element of the PFC circuit in the power supply device may be easily replaced with a semiconductor device including a GaN-HEMT exhibiting small loss, being able to further enhance efficiency of the power source.

The preferred embodiments have been described in detail thus far. However, embodiments of the present disclosure are not limited to the specified embodiments and various alteration and modification may occur within a scope of the present disclosure described in the claims.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiments of the present invention have been described in detail, it should be understood that the various changes, substitutions, and alterations could be made hereto without departing from the spirit and scope of the invention.

What is claimed is:

1. A semiconductor device comprising:
a lead frame that is composed of a lead and a die stage;
a GaN-HEMT that is disposed on the die stage and has a source electrode on a rear surface of the GaN-HEMT, the source electrode being connected to the die stage; and
a MOS-FET that is disposed on the die stage and has a drain electrode on a rear surface of the MOS-FET, the drain electrode being connected to the die stage; wherein
the source electrode of the GaN-HEMT and the drain electrode of the MOS-FET are cascode-connected with each other via the die stage.

2. The semiconductor device according to claim 1, wherein
the source electrode on the rear surface of the GaN-HEMT and the die stage are connected with each other by a soldering paste, and
the drain electrode on the rear surface of the MOS-FET and the die stage are connected with each other by a soldering paste.

3. The semiconductor device according to claim 1, wherein the GaN-HEMT is a depression type GaN-HEMT and is provided with a gate electrode and a drain electrode on a front surface thereof.

4. The semiconductor device according to claim 3, wherein
the lead includes a plurality of leads,
a first lead among the plurality of leads is connected with the gate electrode by a first bonding wire, and
a second lead among the plurality of leads is connected with the drain electrode by a second bonding wire.

5. The semiconductor device according to claim 1, wherein the MOS-FET is an enhancement type MOS-FET and is provided with a gate electrode and a source electrode on a front surface thereof.

6. The semiconductor device according to claim 5, wherein
the lead includes a plurality of leads,
a first lead among the plurality of leads is connected with the gate electrode by a first bonding wire, and
a second lead among the plurality of leads is connected with the source electrode by a second bonding wire.

7. The semiconductor device according to claim 1, further comprising:
a control chip that is disposed on the die stage.

8. A power supply device, comprising:
a DC-DC converter; and
a switching element configured to supply power to the DC-DC converter; wherein
the switching element includes
a lead frame that is composed of a lead and a die stage,
a GaN-HEMT that is disposed on the die stage and has a source electrode on a rear surface of the GaN-HEMT, the source electrode being connected to the die stage, and
a MOS-FET that is disposed on the die stage and has a drain electrode on a rear surface of the MOS-FET, the drain electrode being connected to the die stage, and
the source electrode of the GaN-HEMT and the drain electrode of the MOS-FET are cascode-connected with each other via the die stage.
